(19) United States
(12) Patent Application Publication
(10) Pub. No.: US 2005/0224980 A1
(43) Pub. Date: Oct. 13, 2005

(54) Interconnect adapted for reduced electron scattering

(76) Inventors: Jihperng Leu, Portland, OR (US); Chih-I Wu, Hillsboro, OR (US); Mark Y. Liu, Portland, OR (US); Kevin J. Fischer, Hillsboro, OR (US); Chia-Hong Jan, Portland, OR (US); David Gracias, Baltimore, MD (US)

Correspondence Address: SCHWABE, WILLIAMSON & WYATT, PACWEST CENTER, SUITES 1600-1900, 1211 S.W. FIFTH AVE., PORTLAND, OR, 97204, US

(21) Appl. No.: 10/816,470

(22) Filed: Mar. 31, 2004

(51) Int. Cl. H01L 21/44

(52) U.S. Cl. 257/758

(57) ABSTRACT

A die is provided with an interconnect, and the grain structure of the interconnect is adapted to reduce electron scattering.

### BACKGROUND OF THE INVENTION

1. Field of the Invention

The present invention relates to, but is not limited to, electronic devices, and in particular, to the field of interconnects.

2. Description of Related Art

Integrated circuits use conductive contacts and interconnects to wire together individual devices on a semiconductor substrate, or to conduct input into and output from the integrated circuits. Interconnects may include metals such as, aluminum, copper, silver, gold, tungsten and their alloys. A typical method of forming an interconnect is a damascene process that involves forming an interconnect recess in a dielectric or insulation layer. The interconnect recess (hereinafter referred to as “recess”) may also be lined with a diffusion barrier layer. Often, a conductive seed material is then deposited in the recess. Thereafter, the conductive material is introduced into the recess. The conductive material is then typically planarized. Finally, an annealing process may be carried out either prior to planarization or post planarization.

### BRIEF DESCRIPTION OF THE DRAWINGS

The present invention will be described by way of exemplary embodiments, but not limitations, illustrated in the accompanying drawings in which like references denote similar elements, and in which:

FIG. 1 illustrates an exemplary interconnect coupled to a conductive layer.

FIG. 2 illustrates copper lines with a bamboo grain structure.

FIG. 3 illustrates a process for forming an interconnect using localized annealing according to some embodiments of the invention.

FIGS. 4A to 4H illustrate the interconnect at different stages of the process of FIG. 3 according to some embodiments.

FIG. 5 illustrates localized annealing of an interconnect using resistive annealing according to some embodiments.

FIG. 6 is a block diagram of an example system, according to some embodiments of the invention.

### DETAILED DESCRIPTION OF ILLUSTRATIVE EMBODIMENTS

In the following description, for purposes of explanation, numerous details are set forth in order to provide a thorough understanding of the disclosed embodiments of the present invention. However, it will be apparent to one skilled in the art that these specific details are not required in order to practice the disclosed embodiments of the present invention. In other instances, well-known electrical structures and circuits are shown in block diagram form in order not to obscure the disclosed embodiments of the present invention.

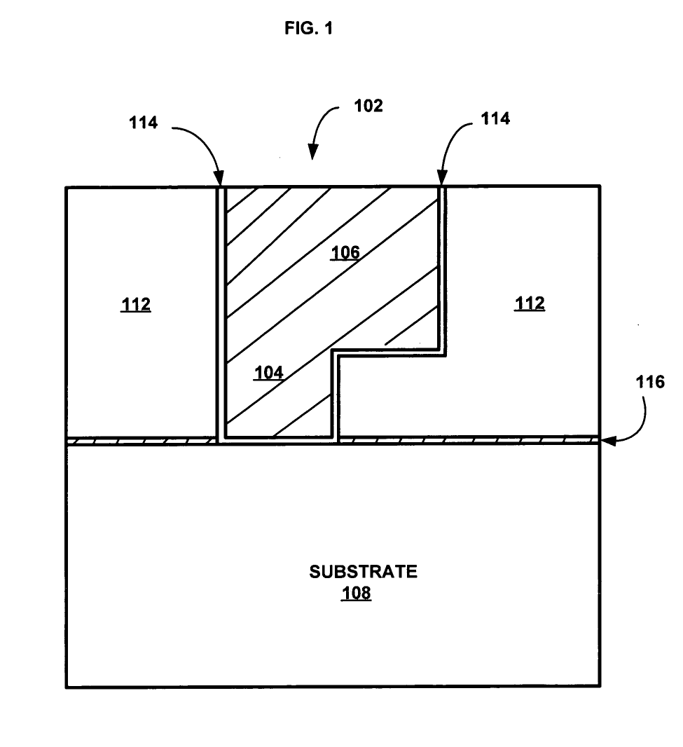

According to embodiments of the invention, interconnects are formed with their grain structures adapted to reduce electron scattering. In various embodiments, the interconnect's grain structure is adapted using localized annealing. An example of an interconnect that may contain such adapted grain structure is depicted in FIG. 1. An interconnect 102 may include, but are not limited to, vias, trenches, traces, conductive layers and the like. In this example, the interconnect 102 comprises of two portions, a via section 104 and a trench section 106. The interconnect 102 may interface with or be imbedded in several layers of material including a dielectric or insulation (herein “insulation”) layer 112 through, for example, a barrier layer 114. An etch stop/diffusion barrier layer (“etch stop layer”) 116 may be disposed between a substrate 108 and the insulation layer 112.

The interconnect 102 may comprise of highly conductive material such as a metal, an alloy and/or other conductive materials. The substrate 108 may be, for example, part of a die or a chip. The insulation layer 112 may be any type of insulation or dielectric material that may be suitable for electrically isolating the interconnect 102. Examples of insulation materials include but are not limited to interlayer dielectrics (ILD) and low-k dielectrics. The barrier layer 114 is typically used to prevent or hinder the diffusion of conductive (e.g., interconnect) material into the surrounding material (e.g., insulation layer 112) but does not prevent the interconnect 102 from electrically coupling with other components. Etch stop layer 116 may serve as etch stop during the patterning of damascene structure without attacking the underlying interconnect 102 or substrate 108. This etch stop layer 116 may also act as a diffusion barrier to prevent or hinder the diffusion of conductive (e.g., interconnect) material into the surrounding material and/or underlying substrate.

In addition to the insulation layer 112, the interconnect 102 may interface with or be located near other components such as other substrate layers, transistors, capacitors, resistors, diodes, and the like. Many of these components may have strict thermal budgets. For example, with some adjacent components, such as the material that is used to form the insulation layer 112, there may be a backend thermal budget of less than or equal to about 450° C. Other components, such as other interconnects, transistors, capacitors, and the like, that are coupled to or are near to the interconnect 102, may also have strict thermal budgets.

Note that the interconnect 102 in FIG. 1 is a depiction of a specific type of interconnect and is provided for illustrative purpose only. Those skilled in the art may recognize that many types of interconnects are possible and that they come in many different sizes, shapes and compositions. Therefore, references to the “interconnect” in the following description is meant to cover all interconnects. Further, interconnects such as the interconnect 102 depicted in FIG. 1 may be stacked on top of each other, each interconnect being associated with a particular layer of a, for example, multi-layer semiconductor substrate and incorporating grain structures adapted to reduce electron scattering according to various embodiments.

The conductivity of a conductive material, such as the material that makes up an interconnect 102, may be compromised due to electron scattering. Electron scattering is the process in which electrons, under the influence of an electric field, scatter at, for example, specific locations such as at grain boundaries, point defects, external interfaces (surfaces), and the like. As a result of the scattering, the movement of electrons that occurs under the influence of an electric field, such as when an electrical current is passing through an interconnect, may be disrupted. As a result, the scattering of the electrons may increase the overall resistivity of the interconnect. In various embodiments, it may be desirable to reduce electron scattering by, for example, reducing or eliminating sites, such as grain boundaries, that may cause electron scattering.

According to some embodiments of the invention, localized annealing processes are employed for producing large grains in an interconnect 102 without exceeding the thermal budgets of surrounding components. For these embodiments, the grain structure of the conductive material (e.g., interconnect material) may be adapted by the localized annealing process to have relatively fewer grain boundaries and thus reduce electron scattering, which in turn may result in reduced resistivity.

The processes may focus a relatively high amount of energy to an interconnect 102 for a relatively short time duration. As a result, there is little impact to the thermal budgets of surrounding components. In doing so, the desired grain structure with reduced electron scattering may be formed within the interconnect 102. The following descriptions provide embodiments for localized annealing of an interconnect 102.

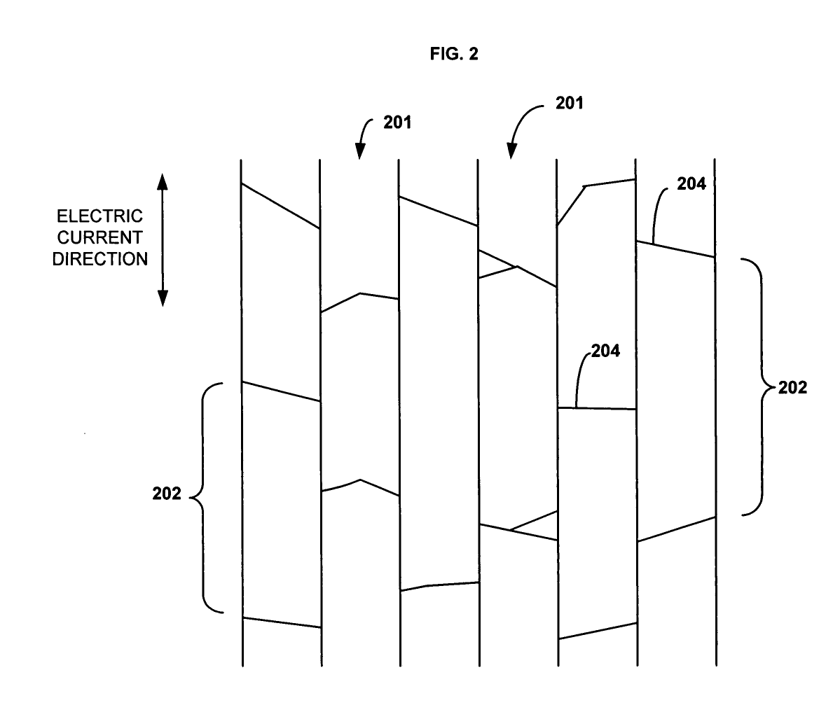

In some embodiments, the grain structure is a bamboo grain structure. Referring to FIG. 2, which depicts copper lines 201 with bamboo grain structures 202. A copper line with grains having large structured grains, such as the bamboo grain structure 202, may have fewer grain boundaries than copper lines comprising of many smaller grains. According to some embodiments, having an adapted grain structure, such as the bamboo grain structure 202, may be desirable in reducing electron scattering and reducing resistivity of an, for example, interconnect.

In order to form the desired example bamboo grain structure 202 in an interconnect 102 without exceeding the thermal budgets of surrounding components, the interconnect 102 may be laser annealed according to some embodiments. In doing so, the thermal budgets of surrounding components and/or interconnect interfaces (e.g., interface between the interconnect 102 and the insulation layer 112) may not be compromised. For these embodiments, a laser may direct coherent light to heat a small area, such as an interconnect site, on a die. Since lasers may be precisely controlled, a laser may be accurately directed to only heat or anneal a localized area. For these embodiments, grain lengths up to ten times the line width have been achieved using for example, a Yttrium Aluminum Garnet (YAG) laser operating at 523 nanometers (nm) and at less than 10 Watts (W) of power for line widths of about 0.25 to 0.5 um.

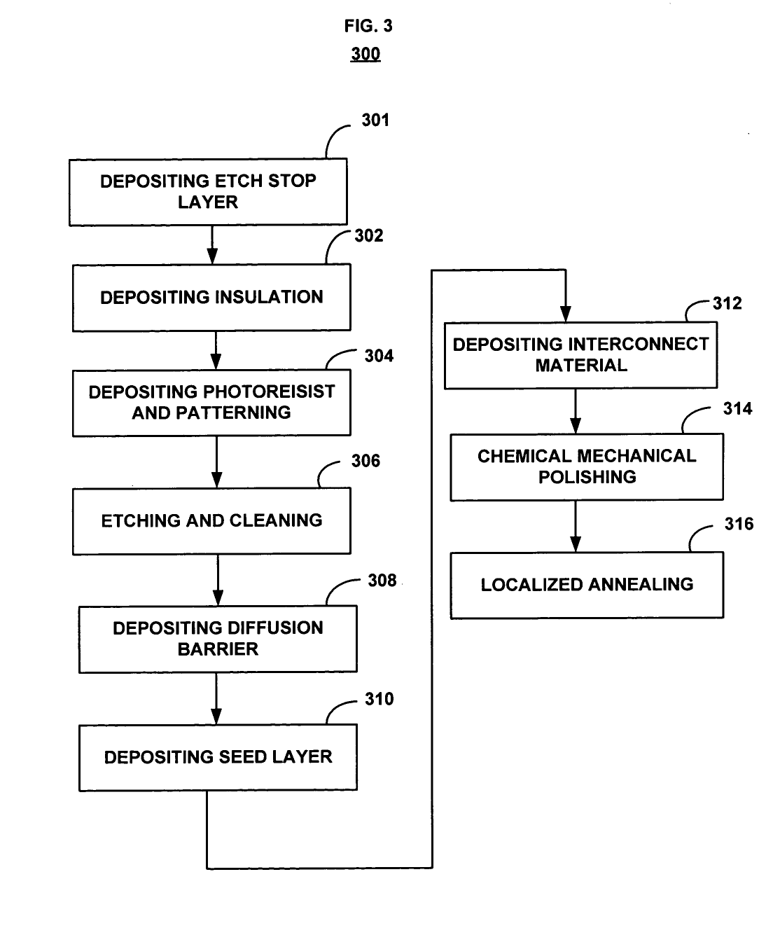

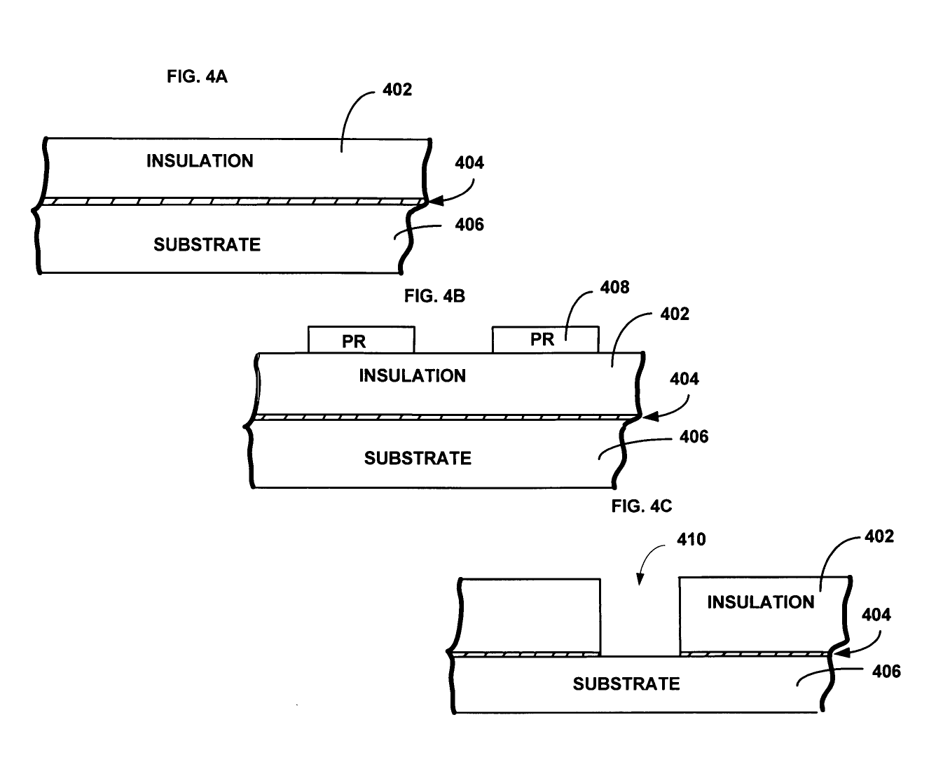

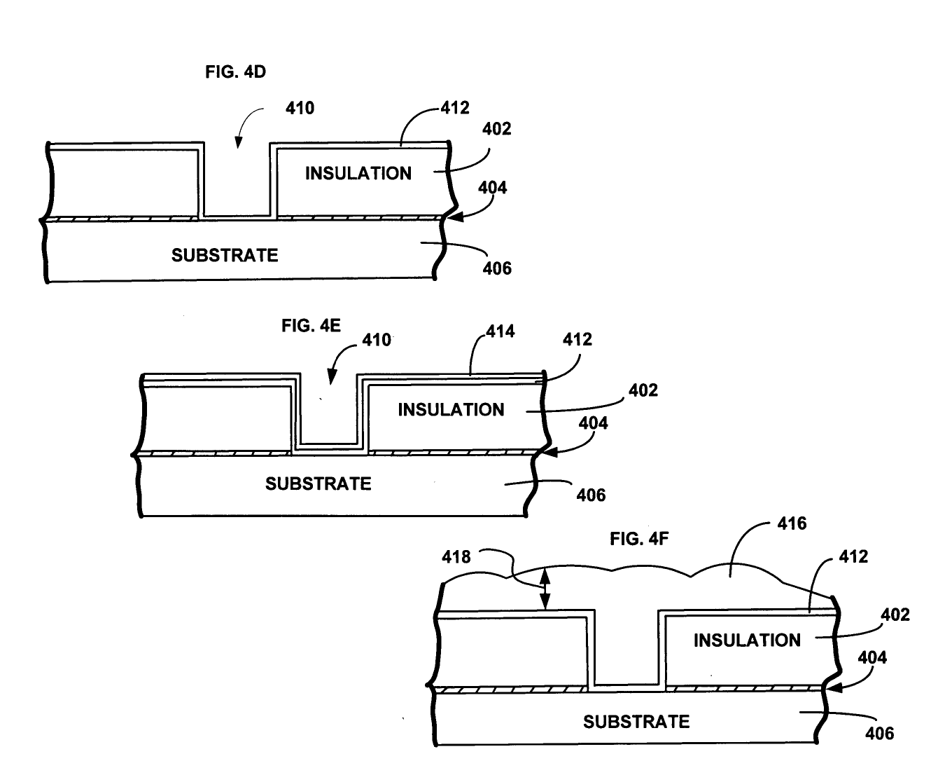

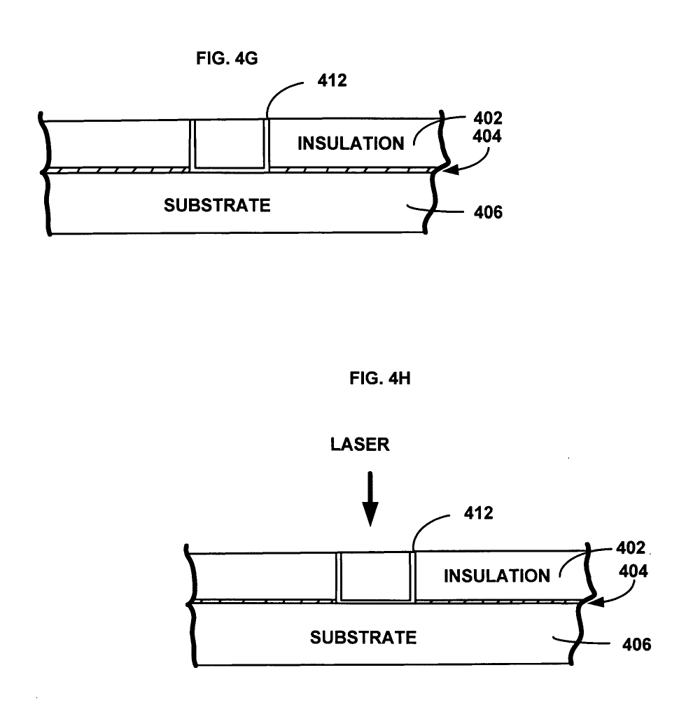

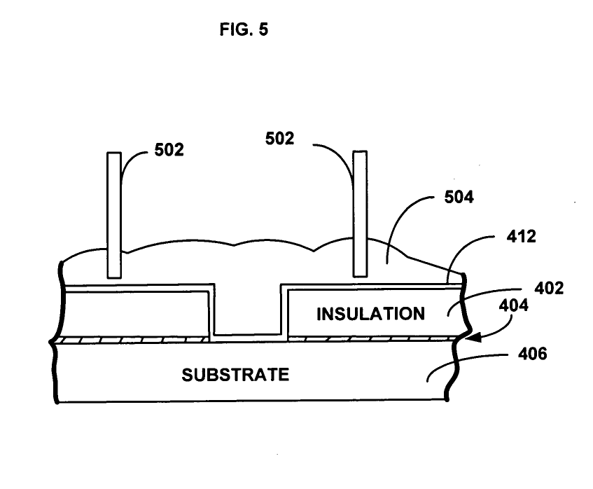

FIG. 3 depicts a process for forming an interconnect 102 with an adapted grain structures using laser annealing according to some embodiments. Although the process 300 is associated with a single or dual damascene scheme, the process may be used with other processes for forming interconnects. FIGS. 4A to 4H are cross sectional views of structures associated with the different stages of the process depicted in FIG. 3.

The process 300 may begin when an etch stop layer 404 is deposited onto a substrate 406 at 301 in accordance with various embodiments. For these embodiments, the etch stop layer 404 may serve two functions, as an etch stop and as a diffusion barrier layer. The etch stop layer 404 may comprise of materials such as but are not limited to silicon nitride, silicon carbide, silicon oxycarbide, silicon oxynitride, and the like. If the etch stop layer 404 comprises of silicon nitride, a chemical vapor deposition process may be used to form the etch stop/diffusion barrier layer 404. In one embodiment, the etch stop layer 404 is deposited to a thickness in the range from about 30 to about 120 nanometers (nm).

In various embodiments, the substrate 406 may be a substrate of a die or a chip. The substrate 406 may include, among other things, semiconductor devices, such as but are not limited to, active and passive devices such as transistors, capacitors, resistors, diffused junctions, gate electrodes, local interconnects, and the like.

According to various embodiments, an insulation layer 402 may next be deposited or formed on the etch stop layer 404 at 302 (see FIG. 4A). The insulation layer 402 may comprise of but are not limited to organic polymers such as polyimides, parylenes, polyarylethers, polynaphthalenes, polyquinolines, bisbenzocyclobutene, polyphenylene, polyarylene, their copolymers or their porous polymers. Other materials that may be used in forming the insulation layer 402 includes various oxides such as silicon dioxide, fluoro-silicate (SiOF), silicon oxynitride, silicon carbide, carbon doped oxides, and the like. The material used for forming the insulation layer 402 may have a low dielectric constant such as less than about 3.5. In some embodiments, the material may have a dielectric constant of between about 1.0 and about 3.0. The insulation layer 402 may be formed using, for example, various techniques such as but are not limited to chemical vapor deposition or spin-on processes.

After depositing or forming the insulation layer 402 on the etch stop layer 404, a photoresist layer 408 may be deposited and patterned on top of the insulation layer 402 to define an interconnect recess for receiving a subsequently deposited conductive (herein “interconnect”) material at 304 (see FIG. 4B). The photoresist layer 408 may be patterned using, for example, a photolithographic process that includes masking the layer of photoresist, exposing the masked layer to light, and then developing the unexposed portions.

Once the photoresist layer 408 is formed and patterned, the exposed portion of the insulation layer 402 may be etched to form an interconnect recess 410 and the photoresist 408 may be removed at 306 (see FIG. 4C) in accordance with various embodiments. If the insulation layer 402 comprises of polymer based film, a plasma formed from a mixture of oxygen, nitrogen, and carbon monoxide may be used to perform that etch step. In various embodiments, the interconnect recess 410 that is formed may reach down to the substrate 406. Following the etching process, the photoresist layer 408 may be removed using, for example, any photoresist removal technique.

Next, a barrier layer 412 may be deposited or formed on the insulation layer 102 and in the interconnect recess 410 at 308 (see FIG. 4D). The barrier layer 412 may inhibit the diffusion of atoms of the interconnect material that will be used to fill the interconnect recess 410 into the surrounding insulation layer 102. The barrier layer 412 may comprise of materials such as but are not limited to tantalum nitride, tantalum nitride/tantalum bilayer, tungsten nitride, titanium nitride, tantalum silicon nitride, tungsten silicon nitride, titanium silicon nitride, and the like. If the barrier layer 412 comprises of tantalum nitride/tantalum bilayer, a physical vapor deposition process may be used to form the barrier layer 412. In one embodiment, the barrier layer 412 is deposited to a thickness in the range from about 10 to about 50 nanometers (nm). In some embodiments, the barrier layer 412 and overburden may be planarized using, for example, a chemical mechanical polishing (CMP) process.

In various embodiments, a conductive seed film (herein “seed film”) 414 may be deposited or formed on the barrier layer 412at 310 (see FIG. 4E). The seed film 414 may be provided as a preparation for plating techniques, such as electroplating and electroless plating. In one embodiment, the conductive seed film 414 comprises of a conductive material, such as copper, that is formed by chemical vapor deposition (CVD) or physical vapor deposition (PVD) techniques.

Once the seed film 414 has been deposited, the interconnect material 416 may be deposited or formed onto the interconnect recess 410 using, for example, an electroplating process at 312 (see FIG. 4F) in accordance with some embodiments. In addition to filling the interconnect recess 410, an overburden 418 of excess interconnect material 416 may be formed on top of the insulation layer 402. For these embodiments, the electroplating process may be carried out by, for example, immersing or contacting, for example, the die (that contains the interconnect recess 410) with an aqueous solution containing metal ions, such as copper sulfate-based solution, and reducing the ions onto a cathodic surface. Various metals such as tungsten (W), copper (Cu), silver (Ag), gold (Au), aluminum (Al) and their alloys may be used as interconnect material 416. In addition, copper alloys such as copper-magnesium, copper-nickel, copper-tin, copper-indium, copper-cadmium, copper-zinc, copper-bismuth, copper-ruthenium, copper-tungsten, copper-cobalt, copper-palladium, copper-gold, copper-platinum, and copper-silver. After the recess filling process is completed, an overburden 418 of the deposited interconnect material 416 may be present on the insulation layer 402.

Once the interconnect material 416 has been deposited onto the insulation layer 402 and into the interconnect recess 410, a planarization process may be performed at 314 (see FIG. 4G) to remove the excess overburden 418 from the top of the insulation layer 402. In one embodiment, a chemical mechanical polishing process may be employed to remove the excess overburden 418. In other embodiments, other processes may be employed to remove the excess overburden 418.

After the removal of the overburden 418, the interconnect material 416 that is in the interconnect recess 410 may than be locally annealed at 316 (see FIG. 4H). In various embodiments, the localized annealing is performed using laser annealing. The laser may be but is not limited to a YAG laser, a CO₂ laser, an Ar+ laser, and the like. The wavelength of the laser may depend upon a number of factors including for example, the type of laser being used, the power level, the type of interconnect material being annealed, the annealing time, and the like. For example, according to one embodiment, the laser is a YAG laser that generates coherent light with wavelengths of about 1.064 nm. In another embodiment, the laser is a CO₂ laser that generates coherent light with wavelengths of about 10.6 microns. In yet another embodiment, the laser is an Ar+ laser that generates coherent light with wavelengths of about 514 to about 488 nm. The wavelengths provided above are for illustrative purposes only and should not be considered limiting. As described previously, a number of factors may influence which wavelengths to be used. Thus, a wide range of wavelengths may be used.

The annealing time may also vary depending on a number of factors including but are not limited to the type of laser used, laser power, wavelength, interconnect material, and the like. In some embodiments, the annealing time may be about 30 to about 60 μsec. According to one embodiment, a CO₂ laser with power of about 50 to about 200 Watts (W) and preferably greater than 100 W may be used. For the embodiment, the anneal time may range from about 1 to about 200 μsec.

According to another embodiment of the invention, the grain structure of an interconnect 102 may be adapted using localized annealing via resistive annealing. In resistive annealing, interconnect material may be annealed by passing an electric current through the interconnect material and using the interconnect material's own natural resistivity, generate localized heat. The generated heat may then induce grain growth and increase grain size, thereby reducing electron scattering. This may be accomplished without exceeding the thermal budgets of surrounding components and interfaces by, for example, passing electric currents in short pulses through the interconnect material of the interconnect being formed.

Referring to FIG. 5, which depicts an interconnect that has been electroplated using electrodes according to some embodiments of the invention. In this example, electrodes 502 were used to deposit interconnect material 504 and is imbedded into the interconnect material 504. In other embodiments, the electrodes 502 may simply be electrically coupled to the interconnect material 504 rather than being imbedded into the interconnect material 504. According to one embodiment, the electrodes 502 used for electroplating may be used to pass a pulse or pulses of electrical current through the interconnect material after the interconnect material 504 has been deposited. The resistance of the interconnect material 504 and the electrical current may generate sufficient heat to induce grain growth within the interconnect material.

According to some embodiments, the overall process for forming interconnects with large grain structures using resistive annealing may be generally similar to the process depicted in FIG. 3. However, for these embodiments, the resistive annealing (i.e., localized annealing 316) may be performed prior to the chemical mechanical polishing process (reference 314 while the excess overburden 418 is still present on top of the insulation layer 402.

A determination may be empirically made as to the electrical current requirement for obtaining a particular temperature point in an interconnect using resistive annealing. For instance, the power generated electrically in a conductive material is known to equal to I²R, where I is the current passing through the material and R is the resistance of the material. In an equilibrium state, the power generated by an electrical current is equal to the power dissipated by radiation, or black body radiation. For example, suppose it is desirable to obtain a temperature of 400 degrees Celsius for a Cu electroplating having a thickness of about 1 μm. Under those conditions, the Cu electroplating will dissipate radiation power of 1 kW/m². For a 1 μm copper film on a silicon wafer, the measured resistivity is about 0.2 Ohm across the wafer. Suppose further that the area of the wafer is about 0.03 m². Based on the following formula, a determination may be made that about 12.2 amps of current must be supplied in order to bring the Cu electroplating to a temperature of 400 degrees Celsius:
I²×R=[radiated power/area]×[area]
I²×0.2 Ohm=1 kW/m²×0.03 m², therefore I=12.2 Amp

Although the embodiments depicted thus far shows localized annealing of an interconnect 102 belonging to a single substrate level, multi-level interconnects may be annealed at the same time in other embodiments. For example, multi-level interconnects may be formed by stacking a plurality of interconnects, such as the interconnect 102 depicted in FIG. 1, one on top of another. Using the robust localized annealing techniques described above, the multi-level interconnects may be heated during a single localized annealing step. In other embodiments, localized annealing of interconnects associated with multiple layers of a multi-layer substrate may be performed one layer at a time.

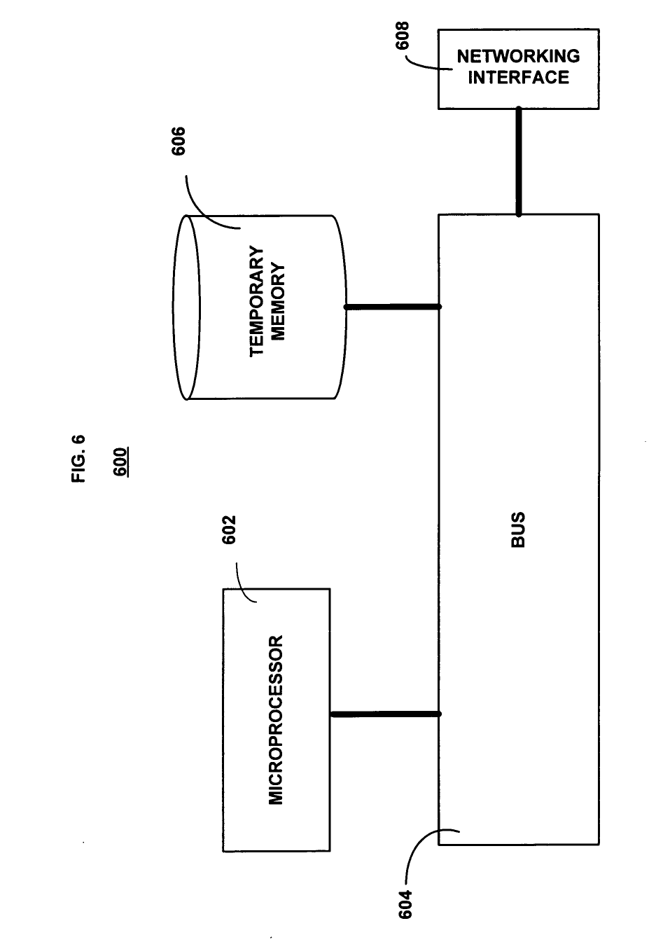

Referring to FIG. 6 showing a system 600 in accordance with some embodiments. The system 600 includes a microprocessor 602 that may be coupled to a bus 604. The system 600 may further include a temporary memory 606 and a networking interface 608. One or more of the above enumerated elements, such as microprocessor 602, memory 606, and so forth, may contain one or more of the interconnects that are advantageously formed employing the localized annealing process described above.

Depending on the applications, the system 600 may include other components, including but not limited to non-volatile memory, chipsets, mass storage (such as hard disk, compact disk (CD), digital versatile disk (DVD), graphical or mathematic co-processors, and so forth.

One or more of the system components may be located on a single chip such as a SOC. In various embodiments, the system 600 may be a personal digital assistant (PDA), a wireless mobile phone, a tablet computing device, a laptop computing device, a desktop computing device, a set-top box, an entertainment control unit, a digital camera, a digital video recorder, a CD player, a DVD player, a network server, or device of the like.

Although specific embodiments have been illustrated and described herein, it will be appreciated by those of ordinary skill in the art that any arrangement which is calculated to achieve the same purpose may be substituted for the specific embodiment shown. This application is intended to cover any adaptations or variations of the embodiments of the present invention. Therefore, it is manifestly intended that this invention be limited only by the claims.

1. A die, comprising:
an insulation layer; and
an interconnect in the insulation layer, the interconnect having been formed with its grain structure adapted to reduce electron scattering.

2. The die of claim 1, wherein the interconnect is adapted to have a bamboo grain structure.

3. The die of claim 1, wherein the grain structure of the interconnect is adapted by localized annealing.

4. The apparatus of claim 1, wherein the interconnect is formed with a material selected from a group consisting of Cu, W, Au, Ag, Al, Cu alloy, W alloy, Au alloy, and Al alloy.

5. The die of claim 1, wherein the die further comprises a diffusion barrier layer, and the interconnect is formed on the diffusion barrier layer.

6. The die of claim 1, wherein the insulation layer having a thermal budget of less than or equal to about 450 degrees Celsius.

7. The die of claim 1, wherein the grain structure of the interconnect is adapted by localized annealing employing laser annealing.

8. The die of claim 1, wherein the grain structure of the interconnect is adapted by localized annealing employing resistive annealing.

9. A method, comprising:
forming an insulation layer on a die; and
forming an interconnect in the insulation layer, including adapting its grain structure to reduce electron scattering.

10. The method of claim 9, wherein said adapting comprises localized annealing the interconnect.

11. The method of claim 10, wherein the localized annealing comprises laser annealing using a selected one of a YAG, a CO2 or an Ar+ laser.

12. The method of claim 10, wherein the localized annealing comprises laser annealing using a CO2 laser operating at about 50 to about 200 Watts and the annealing time is in the range of about 1 to about 200 μsec.

13. The method of claim 9, wherein the forming of an interconnect comprises depositing a metal selected from a group consisting of Cu, W, Au, Ag, Al, Cu alloy, W alloy, Au alloy, and Al alloy.

14. The method of claim 9, wherein the forming of an interconnect is in an insulation layer having a thermal budget of less than or equal to about 450 degrees Celsius.

15. The method of claim 9, wherein the adapting comprises localized annealing of the interconnect by resistive annealing.

16. The method of claim 15, wherein the resistive annealing comprises coupling an electrode to the interconnect.

17. The method of claim 16, wherein the electrode is an electrode used for electroplating the interconnect.

18. The method of claim 16, further comprises passing an electrical pulse through the interconnect via the electrode.

19. The method of claim 9, wherein the forming of an interconnect further comprises forming a seed layer.

20. A system, comprising:
a die, including
an insulation layer; and
an interconnect imbedded in the insulation layer, the interconnect having its grain structure adapted to reduce electron scattering;
a bus coupled to the die; and
a networking interface coupled to the bus.

21. The system of claim 20, wherein the interconnect is adapted to have a bamboo grain structure.

22. The system of claim 20, wherein the grain structure of the interconnect is adapted by localized annealing employing laser annealing.

23. The system of claim 20, wherein the grain structure of the interconnect is adapted by localized annealing employing resistive annealing.

24. The system of claim 20, wherein the system is a selected one of a set-top box, a digital camera, a CD player, or a DVD player.
